(19) United States
(12) Patent Application Publication
(10) Pub. No.: US 2026/0304698 A1
(43) Pub. Date: Oct. 1, 2026

(54) A HEAT EXCHANGER FOR AN ELECTRONIC COMPONENT OF A SERVER

(71) Applicant: Y.E. Hub Armenia LLC, Yerevan (AM)

(72) Inventors: Konstantin Aleksandrovich KLUBNICHKIN, Moscow (RU); Igor Iurevich ZNAMENSKII, d Drozhzhino (RU); Andrey Alekseevich BLOKHIN, Moscow (RU); Andrey Olegovich KOROLENKO, Moscow (RU); Nikita Aleksandrovich VEDENEEV, Vladimir (RU); Ivan Vladimirovich PROSTOV, Moscow (RU); Oleg Valerevich FEDOROV, Moscow (RU); Aleksandr Alekseevich KONOVALOV, Krasnogorsk (RU); Aleksey Yurievich ANDRIANOV, Klin (RU); Sergey Aleksandrovich YARMOLENKO, Pushkino (RU); Ilya Sergeevich GALKIN, Volgograd (RU); Pavel Vladimirovich BELOVODSKY, Gus-Khrustalny (RU); Lev Sergeevich GOLOTYUK, Moscow (RU)

(21) Appl. No.: 18/881,970

(22) PCT Filed: Jul. 7, 2022
(86) PCT No.: PCT/RU2022/000221

§ 371 Date: Jan. 7, 2025

(51) Int. Cl. H05K 7/20

(52) U.S. Cl. CPC H05K 7/20336; H05K 7/20809

(57) ABSTRACT

The disclosed heat exchanger is for an electronic component of a server. The heat exchanger comprising: i) a body configured to be positioned adjacent to the electronic component; ii) a heat pipe extending away from the body for conducting heat absorbed by the body from the electronic component; iii) a plurality of disc-shaped fins located and spaced apart along the heat pipe, the plurality of disc-shaped fins being coaxial with the heat pipe; and iv) a fan for driving air in between the plurality of disc-shaped fins.

### CROSS-REFERENCE

The present application is a U.S. national stage entry of International Patent Application No. PCT/RU2022/000221, filed on Jul. 7, 2022, entitled “A HEAT EXCHANGER FOR AN ELECTRONIC COMPONENT OF A SERVER”.

### TECHNICAL FIELD

The present technology generally relates heat exchangers, and, in particular, to a heat exchanger for an electronic component of a server.

### BACKGROUND

Heat exchangers for dissipating the heat of a heat-generating electronic component are known in the art, and traditional heat exchangers generally comprised of a set of heat pipes coupled with a component which may be fitted in good thermal contact with a heat exchanger plates (e.g., heatsinks). Such traditional heat exchangers are passive devices with a large thermal capacity and with a large surface area relative to its volume. The heat pipes and the heat exchanger plates are generally made of a metal with high thermal conductivity such as aluminium or copper and incorporate fins to increase the surface area. Additionally, a fan is to be used to circulate air through the heat exchanger plates.

Generally speaking, such traditional heat exchanger uses heat pipes for rapid transfer of the heat from the processor (being locked in the bottom of the construction) to the plurality of plates components for further heat dissipation. Additionally, the solution may use multiple fans for increasing airflow and thus increasing heat exchange with the environment.

However, even using the optimal heat exchanger architecture in terms of surface, using the high-quality materials in terms of conductivity, it may still be very difficult to overcome heat dissipation above a certain limit. It may also be very difficult to increase the fan rotation speed indefinitely increasing air circulation again and again.

Generally, there exist several heat exchangers for cooling electronic components. For example, “CN 106371535 A” discloses a parallel type CPU cooling device which comprises a CPU, a semiconductor refrigeration slice, a heat conduction block, a plurality of first heat pipes, a plurality of second heat pipes and a cooling fan. The upper end of the CPU is provided with a first heat conduction adhesive layer, the cold end of the semiconductor refrigeration slice and the lower end of the heat conduction block are fixed to the first heat conduction adhesive layer, the semiconductor refrigeration slice and the heat conduction block are arranged in parallel, and the sum of the cold end area of the semiconductor refrigeration slice and the area of the end face of the lower end of the heat conduction block is equal to the area of the upper surface of the first heat conduction adhesive layer. The end face of the hot end of the semiconductor refrigeration slice and the end face of the upper end of the heat conduction block are covered with a second heat conduction adhesive layer, the second heat conduction adhesive layer located over the semiconductor refrigeration slice is connected with the cooling fan through the first heat pipes, and the second heat conduction adhesive layer located over the heat conduction block is connected with the cooling fan through the second heat pipes. The semiconductor refrigeration slice is further adopted to perform cooling while heat is transferred and dissipated through the heat conduction block, so as to reduce the temperature rise range during work of the CPU, and thus the working efficiency of the CPU is improved.

With this said, there is an interest in developing an efficient heat exchanger for an electronic component of a server.

### SUMMARY

Embodiments of the present technology have been developed based on developers' appreciation of at least one technical problem associated with the prior art solutions.

Developers of the present technology have realized that with the conventional heat exchanger may not adequately perform with heat-generating electronic components that require heat dissipation above a certain level. Moreover, the plates associated with the conventional heat exchangers having large size have lower effectiveness per unit surface area in terms of removing the heat.

Hence, it can be said that in at least some embodiments of the present technology, the developers of the present technology have devised a heat exchanger for an electronic component of a server. The heat exchanger, in at least some embodiments, may have plurality of disc-shaped fins located and spaced apart along heat pipes extending away from a body. The plurality of disc-shaped fins may result in an increased airflow and remove the heat generated by the electronic component associated with the server more efficiently as compared to the conventional heat exchangers.

In accordance with a first broad aspect of the present technology, there is provided a heat exchanger for an electronic component of a server, the heat exchanger comprising: a body configured to be positioned adjacent to the electronic component; a heat pipe extending away from the body for conducting heat absorbed by the body from the electronic component; a plurality of disc-shaped fins located and spaced apart along the heat pipe, the plurality of disc-shaped fins being coaxial with the heat pipe; and a fan for driving air in between the plurality of disc-shaped fins.

In some embodiments of the heat exchanger, wherein the inner radius between 3-6 mm and the outer radius is between 15 to 26 mm.

In some embodiments of the heat exchanger, wherein the given one from the plurality of disc-shaped fins has a surface area is between 296 to 1005 mm².

In some embodiments of the heat exchanger, wherein the plurality of disc-shaped fins has a combined surface area between 207.2 to 703.5 m².

In some embodiments of the heat exchanger, wherein a distance between a pair of neighboring disc-shaped fins from the plurality of disc-shaped fins is between 1 to 30 mm.

In some embodiments of the heat exchanger, wherein the plurality of disc-shaped fins along the heat pipe extend along respective parallel planes.

In some embodiments of the heat exchanger, wherein the heat pipe is a first heat pipe and the plurality of disc-shaped fins is a first plurality of disc-shaped fins, the heat exchanger further comprising: a second heat pipe extending away from the body for conducting heat absorbed by the body from the electronic component, the first heat pipe and the second heat pipe being substantially parallel; and a second plurality of disc-shaped fins located and spaced apart along the second heat pipe, the second plurality of disc-shaped fins being coaxial with the second heat pipe.

In some embodiments of the heat exchanger, wherein a distance between a first disc-shaped fin from the first plurality of disc-shaped fins and a closest disc-shaped fin from the second plurality of disc-shaped fins is between 1 to 30 mm.

In some embodiments of the heat exchanger, wherein the fan is configured to generate an airflow around the first heat pipe and the second heat pipe, the first heat pipe and the second heat pipe being arranged in a row of heat pipes facing respective first portions of the airflow.

In some embodiments of the heat exchanger, wherein the heat exchanger further comprises an other row of heat pipes, the row and the other row being arranged in a staggered configuration such that an other heat pipe from the other row faces a second portion of the airflow passing between the first heat pipe and the second heat pipe.

In some embodiments of the heat exchanger, wherein the electronic component is at least one of a Central Processing Unit (CPU) of the server, and a Graphical Processing Unit (GPU) of the server.

In some embodiments of the heat exchanger, wherein the electronic component has an operational temperature is 77 degrees Celsius.

In some embodiments of the heat exchanger, wherein the server is located in a server rack.

In accordance with a second broad aspect of the present technology, there is provided a heat exchanger for an electronic component of a server, the heat exchanger comprising: a body configured to be positioned adjacent to the electronic component; a plurality of heat pipes extending away from the body for conducting heat absorbed by the body from the electronic component, the plurality of heat pipes being substantially parallel, each one from the plurality of heat pipes having a respective plurality of fins extending therefrom; a fan for generating an airflow around the plurality of parallel heat pipes, the plurality of heat pipes being arranged in rows of heat pipes facing the airflow, a first row and a second row amongst the rows being arranged in a staggered configuration such that the first row faces first portions of the airflow and the second row faces second portions of the airflow, the second portions passing between neighboring heat pipes from the first row.

In some embodiments of the heat exchanger, wherein the body has two opposite walls, the first row and the second row extending from a given one of the two opposite walls, a third row and a fourth row amongst the rows extending from the other one of the two opposite walls.

In some embodiments of the heat exchanger, wherein a given intra-row pitch of a given row is a distance between a given fin of a given heat pipe in the given row and a closest fin of a neighboring heat pipe in the given row, a first intra-row pitch of the first row being equal to a second intra-row pitch of the second row, a third intra-row pitch of the third row being equal to a fourth intra-row pitch of the fourth row, the first intra-row pitch being different from the third intra-row pitch.

In some embodiments of the heat exchanger, wherein the respective plurality of fins of each one of the plurality of heat pipes includes disc-shaped fins.

In some embodiments of the heat exchanger, wherein the electronic component is at least one of a Central Processing Unit (CPU) of the server, and a Graphical Processing Unit (GPU) of the server.

In some embodiments of the heat exchanger, wherein the electronic component has an operational temperature is 77 degrees Celsius.

In the context of the present specification, a “server” is a computer program that is running on appropriate hardware and is capable of receiving requests (e.g. from electronic devices) over the network, and carrying out those requests, or causing those requests to be carried out. The hardware may be one physical computer or one physical computer system, but neither is required to be the case with respect to the present technology. In the present context, the use of the expression a “at least one server” is not intended to mean that every task (e.g. received instructions or requests) or any particular task will have been received, carried out, or caused to be carried out, by the same server (i.e. the same software and/or hardware); it is intended to mean that any number of software elements or hardware devices may be involved in receiving/sending, carrying out or causing to be carried out any task or request, or the consequences of any task or request; and all of this software and hardware may be one server or multiple servers, both of which are included within the expression “at least one server”.

In the context of the present specification, unless provided expressly otherwise, the words “first”, “second”, “third”, etc. have been used as adjectives only for the purpose of allowing for distinction between the nouns that they modify from one another, and not for the purpose of describing any particular relationship between those nouns. Thus, for example, it should be understood that, the use of the terms “first server” and “third server” is not intended to imply any particular order, type, chronology, hierarchy or ranking (for example) of/between the server, nor is their use (by itself) intended to imply that any “second server” must necessarily exist in any given situation. Further, as is discussed herein in other contexts, reference to a “first” element and a “second” element does not preclude the two elements from being the same actual real-world element. Thus, for example, in some instances, a “first” server and a “second” server may be the same software and/or hardware, in other cases they may be different software and/or hardware.

Implementations of the present technology each have at least one of the above-mentioned object and/or aspects, but do not necessarily have all of them. It should be understood that some aspects of the present technology that have resulted from attempting to attain the above-mentioned object may not satisfy this object and/or may satisfy other objects not specifically recited herein.

Additional and/or alternative features, aspects and advantages of implementations of the present technology will become apparent from the following description, the accompanying drawings and the appended claims.

### BRIEF DESCRIPTION OF THE FIGURES

Further features and advantages of the present technology will become apparent from the following detailed description, taken in combination with the appended drawings, in which:

FIG. 1 depicts a perspective view of a heat exchanger in accordance with various non-limiting embodiments of the present disclosure;

FIG. 2 illustrates a top view of the heat exchanger in accordance with various non-limiting embodiments of the present disclosure;

FIG. 3 illustrates another top view of the heat exchanger in accordance with various non-limiting embodiments of the present disclosure; and

FIG. 4 illustrates airflow diagram of the heat exchanger, in accordance with various non-limiting embodiments.

It is to be understood that throughout the appended drawings and corresponding descriptions, like features are identified by like reference characters. Furthermore, it is also to be understood that the drawings and ensuing descriptions are intended for illustrative purposes only and that such technology do not provide a limitation on the scope of the claims.

### DETAILED DESCRIPTION

The examples and conditional language recited herein are principally intended to aid the reader in understanding the principles of the present technology and not to limit its scope to such specifically recited examples and conditions. It will be appreciated that those skilled in the art may devise various arrangements which, although not explicitly described or shown herein, nonetheless embody the principles of the present technology and are included within its spirit and scope.

Furthermore, as an aid to understanding, the following description may describe relatively simplified implementations of the present technology. As persons skilled in the art would understand, various implementations of the present technology may be of a greater complexity.

In some cases, what are believed to be helpful examples of modifications to the present technology may also be set forth. This is done merely as an aid to understanding, and, again, not to define the scope or set forth the bounds of the present technology. These modifications are not an exhaustive list, and a person skilled in the art may make other modifications while nonetheless remaining within the scope of the present technology. Further, where no examples of modifications have been set forth, it should not be interpreted that no modifications are possible and/or that what is described is the sole manner of implementing that element of the present technology.

Moreover, all statements herein reciting principles, aspects, and implementations of the present technology, as well as specific examples thereof, are intended to encompass both structural and functional equivalents thereof, whether they are currently known or developed in the future. Thus, for example, it will be appreciated by those skilled in the art that any block diagrams herein represent conceptual views of illustrative circuitry embodying the principles of the present technology. Similarly, it will be appreciated that any flowcharts, flow diagrams, state transition diagrams, pseudo-code, and the like represent various processes which may be substantially represented in computer-readable media and so executed by a computer or processor, whether or not such computer or processor is explicitly shown.

The functions of the various elements shown in the figures, including any functional block labeled as a “processor” or a “graphics processing unit”, may be provided through the use of dedicated hardware as well as hardware capable of executing software in association with appropriate software. When provided by a processor, the functions may be provided by a single dedicated processor, by a single shared processor, or by a plurality of individual processors, some of which may be shared. In some embodiments of the present technology, the processor may be a general purpose processor, such as a central processing unit (CPU) or a processor dedicated to a specific purpose, such as a graphics processing unit (GPU). Moreover, explicit use of the term “processor” or “controller” should not be construed to refer exclusively to hardware capable of executing software, and may implicitly include, without limitation, digital signal processor (DSP) hardware, network processor, application specific integrated circuit (ASIC), field programmable gate array (FPGA), read-only memory (ROM) for storing software, random access memory (RAM), and non-volatile storage. Other hardware, conventional and/or custom, may also be included.

With these fundamentals in place, we will now consider some non-limiting examples to illustrate various implementations of aspects of the present technology.

In order to make a heat exchanger more effective, there is a requirement to alter the area of the fins associated with the heat exchanger for more air volume to be pumped through the heat exchanger. A typical heat exchanger with plate architecture may allow a limited amount of air to pass through. Such an architecture is effective for normal electronic components with limited temperature limits of the CPU/GPU.

However, when it comes to high temperatures (closer to the constant temperature limits which is more specific for server operations in data centers), the typical heat exchangers are less effective as the typical heat exchangers faces a lack of airflow. With this said, the heat exchanger in accordance with various non-limiting embodiments have higher air bandwidth.

Generally, heat balance associated with the heat exchanger may be represented as:

$$q = α * ( T 1 - T 2 ) * S W \qquad ( 1 )$$

where α may be the heat transfer coefficient (W/(m²*K)) on the type of coolant and its temperature; pressure head temperature, type and flow regime; on the state of the surface and the direction of the flow; for air varies from 10 to 200 (W/(m²*K)), ΔT=T1−T2 may be a difference between air temperature and air exchanger surface (e.g., fins), and S may be heat exchange surface (fin area) m².

The efficiency of the heat exchanger may be improved by increasing the surface-to-air component ΔT and by reducing the inefficient zones of the S component. As a result, pressure loss may be reduced, and airflow may be increased.

More particularly, the heat exchanger in accordance with various non-limiting embodiments, heat pipes may be covered with disc-shaped fins as opposite to the plates. Each of the disc-shaped fins may be vertically planted on the heat pipes. Such a design may allow for more airflow through the heat exchanger allowing for removing more heat.

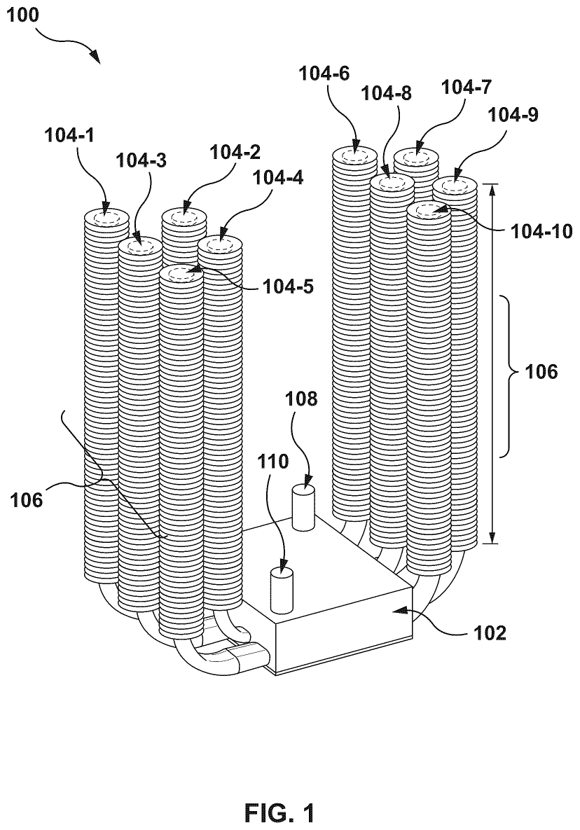

FIG. 1 depicts a perspective view of a heat exchanger 100 in accordance with various non-limiting embodiments of the present disclosure. As shown, the heat exchanger may include a body 102, a plurality of heat pipes 104-1, 104-2, 104-3 . . . 104-10 and a plurality of fins 106. It is to be noted that the heat exchanger 100 may include additional components. However, such components have been omitted from FIG. 1 for the purpose of simplicity.

In certain non-limiting embodiments, the body 102 may be made of a good-conducting material such as aluminium or copper and may have any suitable shape such square, rectangular or the like. The body 102 may be a thermal conducting body. A base of the body 102 may be attached to or adjacent to an electronic component (not illustrated) to absorb heat therefrom. It is to be noted that the electronic component may be associated with a server (not illustrated). Some non-limiting examples of the electronic component may include CPUs, GPUs, DSPs, and the like associated with the server and the server may be stacked in a server rack.

In certain non-limiting embodiments, the body 102 may be based on a liquid cooling block. By way of example, the body 102 may include a liquid inlet 108 and a liquid outlet 110 on a top surface of the body 102. The cooling liquid may inlet from the liquid inlet 108 and may come out from the liquid outlet 110. The cooling liquid may be any suitable cooling liquid for example water, dielectric or the like.

Further, in certain non-limiting embodiments, the plurality of heat pipes 104-1, 104-2, 104-3 . . . 104-10 may be extended away from the body 102 for conducting the heat absorbed by the body 102 from the electronic component. The plurality of heat pipes 104-1, 104-2, . . . 104-10 may be cylindrical in shape and may be made of a good-conducting material such as aluminium or copper.

The body 102 may have two opposite walls, some of the plurality of heat pipes 104-1, 104-2 . . . 104-5 extend away from one of the two opposite walls of the body 102 and others of the plurality of heat pipes 104-6, 104-7, . . . 104-10 extend away from the other one of the two opposite walls of the body 102. Additionally, in certain non-limiting embodiments, the plurality of heat pipes 104-1, 104-2, 104-3, . . . 104-10 may be parallel.

In certain non-limiting embodiment, the plurality of heat pipes 104-1, 104-2, 104-3 . . . 104-10 may be arranged in rows. The rows may be arranged traversal to airflow generated by a fan (discussed later in the disclosure). By way of example, the plurality of heat pipes 104-1, 104-3 and 104-5 may be arranged in a first row and the plurality of heat pipes 104-2 and 104-4 may be arranged in a second row. The first row and the second row may be arranged in a staggered configuration on one of the two opposite walls of the body 102.

In a similar manner, the plurality of heat pipes 104-6, 104-8 and 104-10 may be arranged in a third row and the plurality of heat pipes 104-7 and 104-9 may be arranged in a fourth row. The third row and the fourth row may be arranged in a staggered configuration on the other one of the two opposite walls of the body 102.

In some non-limiting embodiments, the plurality of heat pipes 104-1, 104-2, 104-3 . . . 104-10 may be perpendicular relative to a top surface of the body 102. In other non-limiting, the plurality of heat pipes 104-1, 104-2, 104-3 . . . 104-10 may at any suitable angle between 0 to 90 degrees with respect to the body 102.

In certain non-limiting embodiments, a plurality of fins 106 may be disposed along each one of the plurality of heat pipes 104-1, 104-2, 104-3 . . . 104-10. The plurality of fins 106 may be located and spaced apart along the plurality of heat pipes 104-1, 104-2, 104-3 . . . 104-10. Further, the plurality of fins 106 may be coaxial with the associated plurality of heat pipes 104-1, 104-2, 104-3 . . . 104-10.

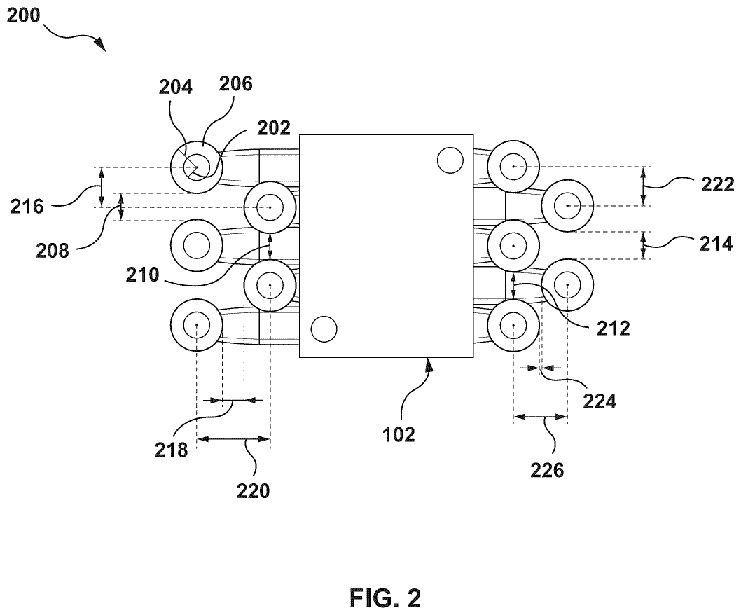

FIG. 2 illustrates a top view 200 of the heat exchanger 100 in accordance with various non-limiting embodiments of the present disclosure. Referring to FIGS. 1 and 2, the plurality of fins 106 may be disc-shaped fins. Further, each one of the plurality of fins 106 may be continuous surface. Each one of a given one of the plurality of fins 106 may have an inner radius 202 and an outer radius 204. Also, each one of the plurality of heat pipes 104-1, 104-2, 104-3 . . . 104-10 may have a radius 206. In certain non-limiting embodiments, the inner radius 202 may be approximately equal to the radius 206.

By way of example, the inner radius 202 may be between 3-6 mm and the outer radius 204 may be between 15 to 26 mm. With these dimensions, each one of the plurality of fins 10 may have a surface area between 296 to 1005 mm². Also, a combined surface area of the plurality of fins 106 associated with each one of the plurality of heat pipes 104-1, 104-2, 104-3 . . . 104-10 may be between 207.2 to 703.5 m². The combined surface area may be referred to as a total surface area of the plurality of fins 106 associated with a given one of the plurality of heat pipes 104-1, 104-2, 104-3 . . . 104-10. By way of example, if a number of fins in the given one of the plurality of heat pipes 104-1, 104-2, 104-3 . . . 104-10 is equal to ten, the combined surface area may be referred to as a total surface of ten fins.

In certain non-limiting embodiments, a distance (for example 216, 222) from a center of the given fin (e.g., 104-1) to a center of another fin (e.g., 104-2) is between 31 to 82 mm. Also, an inter-row pitch (e.g., 218, 224) between the given fin (e.g., 104-4) and another fin (e.g., 104-5) may be equal to 1 to 30 mm.

In certain non-limiting embodiments, a distance between a given fin of a given heat pipe (e.g., 104-1) in the given row (e.g., the first row) and a closest fin of a neighboring heat pipe (e.g., 104-3) in the given row (e.g., the first row) may be referred to as an intra-row pitch.

A first intra-row pitch 208 of the first row may be equal to a second intra-row pitch 210 of the second row. In doing so, the airflow 303 may be effectively distributed between the first row and the second row, resulting in an improved cooling efficiency of the heat exchanger 100. Also, a third intra-row pitch 212 of the third row may be equal to a fourth intra-row pitch 214 of the fourth row. In doing so, the airflow 303 may be effectively distributed between the third row and the fourth row, resulting in an improved cooling efficiency of the heat exchanger 100. In certain non-limiting, the first intra-row pitch 208 may be different from the third intra-row pitch 212. By way of example, the first intra-row pitch 208 and the second intra-row pitch 210 may be equal to 1 to 30 mm. Similarly, the third intra-row pitch 212 and the fourth intra-row pitch 214 may be equal to 1 to 30 mm.

It is to be noted that the above discussed dimensions of the heat exchanger 100 are merely representative examples and the dimensions of the heat exchanger 100 may be modified as per requirements without limiting the scope of the present disclosure.

In certain non-limiting embodiments, the plurality of fins 106 along the associated heat pipe (e.g., 104-3) may extend along respective parallel planes.

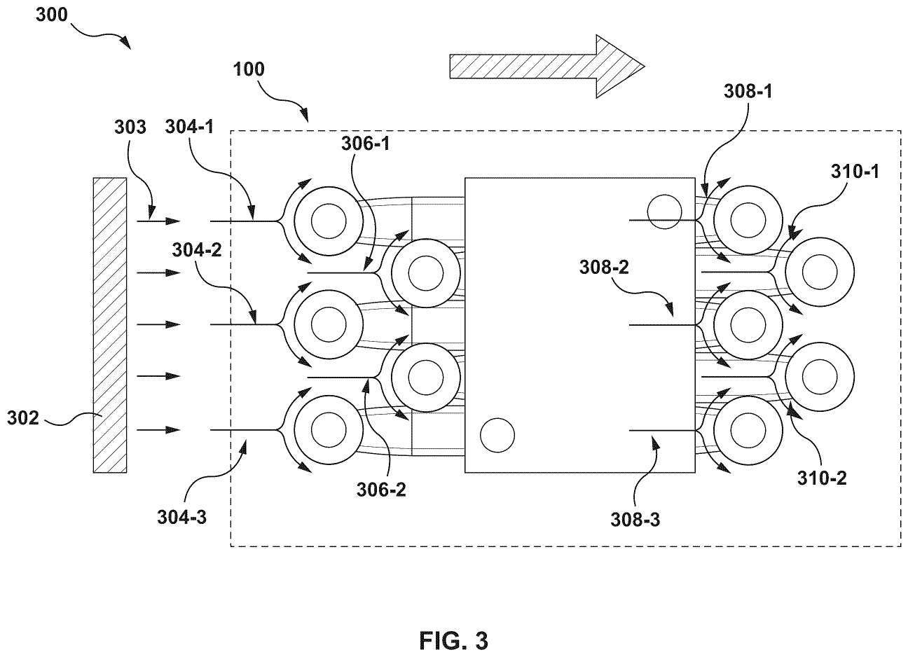

FIG. 3 illustrates a top view 300 of the heat exchanger 100 in accordance with various non-limiting embodiments of the present disclosure. Referring to FIGS. 1 to 3, in certain non-limiting embodiments, the heat exchanger 100 may further include a fan 302. The fan 302 may be placed in close vicinity to the plurality of heat pipes 104-1, 104-2, 104-3 . . . 104-10 and the body 102. It is contemplated that the fan 302 may have associated arrangements that may assist in the functionality of the fan 302. Such arrangements may include electrical connections, fan holder, a fan guard positioned over the fan 302 to protect the fan 302 from contamination and damage during operation or any other suitable arrangement known in the art. Such arrangements have been omitted from the FIG. 3 for the purpose of simplicity.

The fan 302 may be configured to drive air between the plurality of fins 106. In certain non-limiting embodiments, the fan 302 may be configured to generate airflow 303 around the first heat pipe (e.g., 104-1) and the second heat pipe (e.g., 104-3). As previously discussed, the first heat pipe (e.g., 104-1) and the second heat pipe (e.g., 104-3) may be arranged in the first row of heat pipes (104-1, 104-3 and 104-5). The first heat pipe (e.g., 104-1) may be facing a respective first portion 304-1 of the airflow 303. Similarly, the second heat pipe (e.g., 104-3) in the first row of heat pipes (104-1, 104-3 and 104-5) may be facing a respective first portion 304-2 of the airflow 303 and the third heat pipe (e.g., 104-5) in the first row of heat pipes (104-1, 104-3 and 104-5) may be facing a respective first portion 304-3 of the airflow 303.

It is to be noted that the fan 302 pushing the air through the heat exchanger 100 may have a height that may correspond to the height of the electronic component with which the heat exchanger 100 is associated.

In certain non-limiting embodiments, an other heat pipe (e.g., 104-2) from the second row may be facing a respective second portion 306-1 of the airflow 303 passing between the first heat pipe (e.g., 104-1) and the second heat pipe (e.g., 104-3). Similarly, another heat pipe (e.g., 104-4) from the second row may be facing a respective second portion 306-2 of the airflow 303 passing between the second heat pipe (e.g., 104-3) and the third heat pipe (e.g., 104-5). It is to be noted that the first portions 304-1, 304-2, and 304-3 associated with the airflow 303 may be associated with the first row of heat pipes (104-1, 104-3 and 104-5). The second portions 306-1 and 304-2 associated with the airflow 303 may be associated with the second row of heat pipes (104-2 and 104-4).

It may be said that the first row and the second row amongst the rows may be arranged in a staggered configuration. In doing so, the first row including the heat pipes 104-1, 104-3 and 104-5 may face the first portions 304-1, 304-2, and 304-3 of the airflow 303 respectively and the second row including the heat pipes 104-2 and 104-4 may face the second portions 306-1 and 306-2 of the airflow 303 respectively. The second portions 306-1 and 306-2 of the airflow 303 may be passing between the neighboring heat pipes 104-1 and 104-3 and the neighboring heat pipes 104-3 and 104-5 from the first row.

In other words, the first portions 304-1, 304-2, and 304-3 of the airflow 303 may assist in removing the heat between the plurality of fins 106 associated with the plurality of heat pipes (e.g., 104-1, 104-3, and 104-5) associated with the first row. The second portions 306-1 and 306-2 of the airflow 303 may assist in removing the heat between the plurality of fins 106 associated with the heat pipes (e.g., 104-2 and 104-4) associated with the second row.

In a similar manner, the third row and the fourth row amongst the rows may be arranged in a staggered configuration. In doing so, the heat pipe (e.g., 104-6) in the third row of heat pipes (104-6, 104-8, and 104-10) may be facing a respective third portion 308-1 of the airflow 303. Similarly, the heat pipe (e.g., 104-8) in the third row of heat pipes (104-6, 104-8 and 104-10) may be facing a respective third portion 308-2 of the airflow 303 and the heat pipe (e.g., 104-10) in the third row of heat pipes (104-6, 104-8 and 104-10) may be facing a respective third portion 308-3 of the airflow 303.

In certain non-limiting embodiments, a heat pipe (e.g., 104-7) from the fourth row may be facing a respective fourth portion 310-1 of the airflow 303 passing between the heat pipe (e.g., 104-6) and the other heat pipe (e.g., 104-8). Similarly, the heat pipe (e.g., 104-9) from the fourth row may be facing a respective fourth portion 310-2 of the airflow 303 passing between the heat pipe (e.g., 104-8) and the other heat pipe (e.g., 104-10). It is to be noted that the third portions 308-1, 308-2, and 308-3 associated with the airflow 303 may be associated with the third row of heat pipes (104-6, 104-8 and 104-10). The fourth portions 310-1 and 310-2 associated with the airflow 303 may be associated with the fourth row of heat pipes (104-7 and 104-9).

In certain non-limiting embodiments, the first portions 304-1, 304-2, and 304-3 of the airflow 303 may be correspond to the third portions 308-1, 308-2, and 308-3 of the airflow 303. Also, the second portions 306-1 and 306-2 of the airflow 303 may correspond to the fourth portions 310-1 and 310-2 of the airflow 303.

The third portions 308-1, 308-2, and 308-3 of the airflow 303 may assist in removing the heat between the plurality of fins 106 associated with the plurality of heat pipes (e.g., 104-6, 104-8, and 104-10) associated with the third row. The fourth portions 310-1 and 310-2 of the airflow 303 may assist in removing the heat between the plurality of fins 106 associated with the heat pipes (e.g., 104-7 and 104-9) associated with the fourth row.

By virtue of the design of the heat exchanger 100 as discussed above, certain operational parameters of the heat exchanger 100 may be improved. Table 1 depicts a comparison of the operational parameters of the conventional heat exchanger and the heat exchanger 100 (in accordance to at least some of the non-limiting embodiments of the present technology):

TABLE 1

| Operational | Conventional | Heat exchanger |
|---|---|---|
| Parameter | heat exchanger | 100 |
| Pressure loss (Pa) | 390 | 248 |
| Airflow m³/hour | 210 | 398 |
| Surface area S, m² | 0.357 | 0.258 |
| Power, W | 400 | 700 |

As depicted in Table 1, the pressure loss of the heat exchanger 100 may be reduced, airflow of the heat exchanger 100 may be increased, surface area of the heat exchanger may be reduced, and the heat exchanger 100 may be capable of removing the heat from the electronic component having a power rating of 700 W. In additional to the above benefits, an operational temperature of the electronic component located in close vicinity of the heat exchanger 100 may be equal to 77 degrees Celsius. Of note, not each and every of the above benefits needs to be realized in each and every non-limiting embodiment of the present technology.

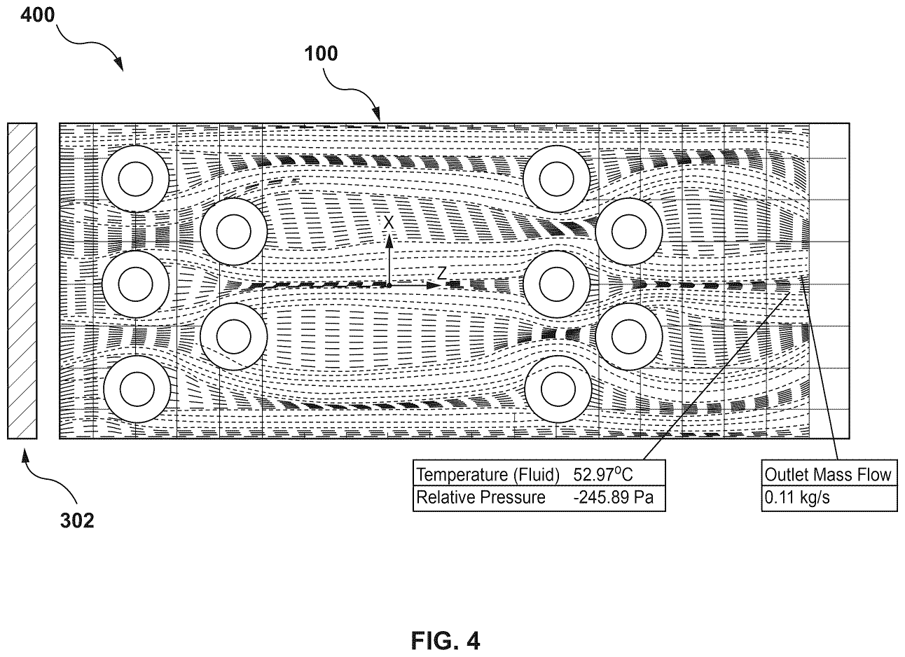

FIG. 4 illustrates an airflow diagram 400 of the heat exchanger 100, in accordance with various non-limiting embodiments. As shown, the fan 302 may blow air towards the heat exchanger 100. By virtue of plurality of disc-shaped fins 106 (as shown in FIG. 1), an increased airflow between the plurality of heat pipes 104-1, 104-2, 104-3 . . . 104-10 is observed. The increased airflow may remove the heat generated by the electronic component associated with the server more efficiently as compared to the conventional heat exchangers. In addition to improving the heat removing capacity of the heat exchanger 100, the plurality of fins 106 may have considerably smaller area as compared to conventional heat exchanger, making the heat exchanger 100 easy to use and install near/around the electronic components associated with the server.

Moreover, it is noted that the plates associated with the conventional heat exchangers having large size have lower effectiveness per unit surface area in terms of removing the heat, given that most of the heat is removed near the heat pipes. Since the plurality of fins 106 have a smaller size and is located near to the heat pipes (e.g., 104-1, 104-2, . . . 104-10), the plurality of fins 106 may have a better effectiveness per unit surface area in terms of removing the heat as compared to conventional plates associated with the conventional heat exchanger.

It will also be understood that, although the embodiments presented herein have been described with reference to specific features and structures, it is clear that various modifications and combinations may be made without departing from such technologies. The specification and drawings are, accordingly, to be regarded simply as an illustration of the discussed implementations or embodiments and their principles as defined by the appended claims, and are contemplated to cover any and all modifications, variations, combinations or equivalents that fall within the scope of the present technology.

1. A heat exchanger for an electronic component of a server, the heat exchanger comprising:
a body configured to be positioned adjacent to the electronic component;
a heat pipe extending away from the body for conducting heat absorbed by the body from the electronic component;
a plurality of disc-shaped fins located and spaced apart along the heat pipe, the plurality of disc-shaped fins being coaxial with the heat pipe; and
a fan for driving air in between the plurality of disc-shaped fins.

2. The heat exchanger of claim 1, wherein a given one from the plurality of disc-shaped fins has an inner radius and an outer radius, the heat pipe having an other radius, the inner radius being equal to the other radius.

3. The heat exchanger of claim 2, wherein the inner radius is between 3-6 mm and the outer radius is between 15 to 26 mm.

4. The heat exchanger of claim 2, wherein the given one from the plurality of disc-shaped fins has a surface area is between 296 to 1005 mm².

5. The heat exchanger of claim 1, wherein the plurality of disc-shaped fins has a combined surface area between 207.2 to 703.5 m².

6. The heat exchanger of claim 1, wherein a distance between a pair of neighboring disc-shaped fins from the plurality of disc-shaped fins is between 1 to 30 mm.

7. The heat exchanger of claim 1, wherein the plurality of disc-shaped fins along the heat pipe extend along respective parallel planes.

8. The heat exchanger of claim 1, wherein the heat pipe is a first heat pipe and the plurality of disc-shaped fins is a first plurality of disc-shaped fins, the heat exchanger further comprising:
a second heat pipe extending away from the body for conducting heat absorbed by the body from the electronic component, the first heat pipe and the second heat pipe being substantially parallel; and
a second plurality of disc-shaped fins located and spaced apart along the second heat pipe, the second plurality of disc-shaped fins being coaxial with the second heat pipe.

9. The heat exchanger of claim 8, wherein a distance between a first disc-shaped fin from the first plurality of disc-shaped fins and a closest disc-shaped fin from the second plurality of disc-shaped fins is between 1 to 30 mm.

10. The heat exchanger of claim 8, wherein the fan is configured to generate an airflow around the first heat pipe and the second heat pipe, the first heat pipe and the second heat pipe being arranged in a row of heat pipes facing respective first portions of the airflow.

11. The heat exchanger of claim 9, wherein the heat exchanger further comprises an other row of heat pipes,
the row and the other row being arranged in a staggered configuration such that an other heat pipe from the other row faces a second portion of the airflow passing between the first heat pipe and the second heat pipe.

12. The heat exchanger of claim 1, wherein the electronic component is at least one of a Central Processing Unit (CPU) of the server, and a Graphical Processing Unit (GPU) of the server.

13. The heat exchanger of claim 1, wherein the electronic component has an operational temperature is 77 degrees Celsius.

14. The heat exchanger of claim 1, wherein the server is located in a server rack.

15. A heat exchanger for an electronic component of a server, the heat exchanger comprising:
a body configured to be positioned adjacent to the electronic component;
a plurality of heat pipes extending away from the body for conducting heat absorbed by the body from the electronic component, the plurality of heat pipes being substantially parallel,
each one from the plurality of heat pipes having a respective plurality of fins extending therefrom;
a fan for generating an airflow around the plurality of parallel heat pipes,
the plurality of heat pipes being arranged in rows of heat pipes facing the airflow,
a first row and a second row amongst the rows being arranged in a staggered configuration such that the first row faces first portions of the airflow and the second row faces second portions of the airflow, the second portions passing between neighboring heat pipes from the first row.

16. The heat exchanger of claim 15, wherein the body has two opposite walls, the first row and the second row extending from a given one of the two opposite walls, a third row and a fourth row amongst the rows extending from the other one of the two opposite walls.

17. The heat exchanger of claim 16, wherein a given intra-row pitch of a given row is a distance between a given fin of a given heat pipe in the given row and a closest fin of a neighboring heat pipe in the given row,
a first intra-row pitch of the first row being equal to a second intra-row pitch of the second row, a third intra-row pitch of the third row being equal to a fourth intra-row pitch of the fourth row, the first intra-row pitch being different from the third intra-row pitch.

18. The heat exchanger of claim 15, wherein the respective plurality of fins of each one of the plurality of heat pipes includes disc-shaped fins.

19. The heat exchanger of claim 15, wherein the electronic component is at least one of a Central Processing Unit (CPU) of the server, and a Graphical Processing Unit (GPU) of the server.

20. The heat exchanger of claim 15, wherein the electronic component has an operational temperature is 77 degrees Celsius.
